(19) United States
(12) Patent Application Publication
(10) Pub. No.: US 2023/0163017 A1
(43) Pub. Date: May 25, 2023

(54) CHANNEL MEMBER AND METHOD FOR MANUFACTURING CHANNEL MEMBER

(71) Applicant: KYOCERA CORPORATION, Kyoto-shi, Kyoto (JP)

(72) Inventors: Kouji TERAMOTO, Koka-shi, Shiga (JP); Shigenobu FURUKAWA, Koka-shi, Shiga (JP)

(21) Appl. No.: 17/915,960

(22) PCT Filed: Mar. 31, 2021
(86) PCT No.: PCT/JP2021/013856

§ 371 Date: Sep. 29, 2022

(30) Foreign Application Priority Data
Mar. 31, 2020 (JP) 2020-063066

(51) Int. Cl. H01L 21/683; H01L 21/304; H01L 21/67

(52) U.S. Cl. CPC H01L 21/6838; H01L 21/304; H01L 21/67248

(57) ABSTRACT

A channel member consists essentially of a dense ceramic body including an upper surface and a lower surface, and having a thickness of 50 mm or more between the upper surface and the lower surface and an area in a plan view equal to or greater than an area of a circle with a diameter of 350 mm. The channel member includes a first channel inside the dense ceramic body. A depth of the first channel is greater than a width of the first channel.

### TECHNICAL FIELD

The present disclosure relates to a channel member including a channel through which a fluid passes, and a method for manufacturing the channel member.

### BACKGROUND ART

In the related art, a semiconductor manufacturing device or an FPD manufacturing device has been used to process a to-be-treated object such as a semiconductor wafer or a glass substrate.

For example, in a semiconductor manufacturing device, when backgrinding (bottom grinding) is performed on a to-be-treated object, heat is generated due to the machining of the to-be-treated object. As a consequence, the to-be-treated object is thermally expanded and the machining accuracy of the to-be-treated object tends to decrease. When the machining accuracy of the to-be-treated object decreases, the to-be-treated object may be damaged.

On the other hand, it has been proposed to cool a to-be-treated object by using a ceramic channel member having a channel formed therein and flowing a cooling fluid through the channel (PTLs 1 and 2).

### CITATION LIST

### Patent Literature

PTL 1: WO 2013/179936

PTL 2: JP 2017-212328

### SUMMARY OF INVENTION

In an aspect of the present disclosure, a channel member consists essentially of a dense ceramic body including an upper surface and a lower surface, and having a thickness of 50 mm or more between the upper surface and the lower surface and an area in a plan view equal to or greater than an area of a circle with a diameter of 350 mm. The channel member includes: a first channel inside the dense ceramic body. A depth of the first channel along the direction of the thickness is greater than a width of the first channel.

In another aspect of the present disclosure, a channel member consists essentially of a dense ceramic body including an upper surface and a lower surface, and having a thickness of 50 mm or more between the upper surface and the lower surface and an area in a plan view equal to or greater than an area of a circle with a diameter of 350 mm. The dense ceramic body consists essentially of three or more laminated layers of ceramic substrates. Except for a ceramic substrate on the uppermost layer, the ceramic substrates include a channel. For a ceramic substrate located above and a ceramic substrate located below of the ceramic substrates including a channel, the ceramic substrate located above is laminated on the ceramic substrate located below of the ceramic substrates including a channel, a depth of the channel of the ceramic substrate located above is greater than a width of the channel of the ceramic substrate located above, and is greater than half of a thickness of the ceramic substrate located above.

In an aspect of the present disclosure, a method for manufacturing a channel member includes: preparing a first powder compact and a second powder compact made by forming a ceramic powder; forming a groove on an upper surface of the first powder compact, the groove being configured to be a first channel having a depth greater than a width; applying a bonding paste containing the ceramic powder to at least one of the upper surface of the first powder compact, which is formed with the groove, or a lower surface of the second powder compact; forming a laminated body in which the first powder compact and the second powder compact are laminated via the paste; heating the laminated body at a temperature lower than a firing temperature to degrease the laminated body; and producing a channel member by firing the laminated body. The channel member includes a dense ceramic body having a thickness of 50 mm or more and an area in a plan view equal to or greater than an area of a circle with a diameter of 350 mm.

In another aspect of the present disclosure, a method for manufacturing a channel member includes: preparing a first powder compact, a second powder compact, and a third powder compact made by forming a ceramic powder; forming a first groove on an upper surface of the first powder compact, the first groove being configured to be a first channel having a depth greater than a width, and forming a second groove on an upper surface of the third powder compact, the second groove being configured to be a second channel having a depth greater than a width; applying a bonding paste containing the ceramic powder to at least one of the upper surface of the first powder compact, which is formed with the first groove, or a lower surface of the third powder compact; applying a bonding paste containing the ceramic powder to at least one of the upper surface of the third powder compact, which is formed with the second groove, or a lower surface of the second powder compact; superimposing the upper surface of the first powder compact and the lower surface of the third powder compact via the bonding paste, and superimposing the upper surface of the third powder compact and the lower surface of the second powder compact via the bonding paste, thereby forming a laminated body in which the first powder compact, the third powder compact, and the second powder compact are laminated in this order; heating the laminated body at a temperature lower than a firing temperature and degreasing the laminated body; and producing a channel member by firing the laminated body. The channel member consists essentially of a dense ceramic body having a thickness of 50 mm or more and an area in a plan view equal to or greater than an area of a circle with a diameter of 350 mm.

### BRIEF DESCRIPTION OF THE DRAWINGS

FIG. 1 is a perspective view illustrating a channel member according to an embodiment of the present disclosure.

FIG. 2(a) is a schematic cross-sectional view of the channel member illustrated in FIG. 1. FIG. 2(b) is an enlarged view of part A in FIG. 2(a). FIG. 2(c) is an enlarged view of part B in FIG. 2(a).

FIG. 3 is a plan view illustrating an example of a first channel used as a suction path for vacuum suction.

FIG. 4 is a plan view illustrating an example of a second channel through which a temperature control fluid flows.

FIG. 5 is a schematic view for explaining a method for manufacturing the channel member illustrated in FIG. 1.

FIG. 6(a) is a perspective view illustrating a channel member according to another embodiment of the present disclosure. FIG. 6(b) is a cross-sectional view of the channel member. FIG. 6(c) is an enlarged view of part C in FIG. 6(b). FIG. 6(d) is an enlarged view of part D in FIG. 6(b).

FIG. 7 is a cross-sectional view illustrating a channel member according to further another embodiment of the present disclosure.

### DESCRIPTION OF EMBODIMENTS

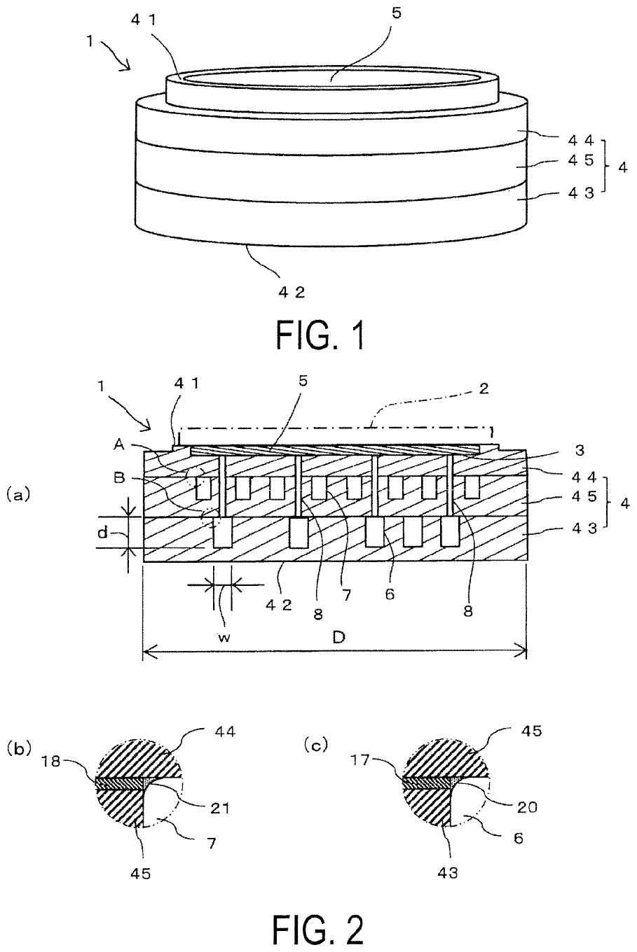

Hereinafter, in an embodiment of the present disclosure, a channel member will be described with reference to FIGS. 1 to FIG. 7. The present embodiment provides a channel member, which is easy to degrease at the time of manufacturing and has improved uniformity of temperature distribution and response of temperature control, and a method for manufacturing the same.

Drawings used in the following description are schematic, and dimensional ratios and the like on the drawings do not always match the actual ones.

FIG. 1 is a perspective view illustrating a channel member according to an embodiment of the present disclosure, and FIG. 2 is a schematic cross-sectional view thereof. In the present embodiment, a channel member 1 is used as a vacuum chuck (suction member) for sucking and holding a to-be-treated object 2, such as a semiconductor wafer, in a backgrinding (bottom grinding) process and a polishing process of the to-be-treated object 2. As illustrated in FIGS. 1 and 2, the channel member 1 includes a plate-shaped body 4 formed with a recess 3 opened in an upper surface 41, and a porous body 5 housed in the recess 3 of the body 4 and forming a suction or of the to-be-treated object 2.

The body 4 is consisting essentially of a dense ceramic body (sintered compact). Since dense ceramics have a smaller porosity than porous ceramics, the dense ceramics have high rigidity and are not easily deformed. The porosity of the body 4 is preferably 5% or less, particularly 3% or less, and more preferably 0.1% or less. The porosity of the body 4 may be determined in accordance with JIS R 1634:1998, and the porosity is substantially open porosity. Examples of the available dense ceramic body include an alumina sintered compact, a cordierite sintered compact, a silicon carbide sintered compact, and an aluminum nitride sintered compact, and among them, it is desirable to use the alumina sintered compact.

In the present embodiment, the alumina sintered compact refers to a sintered compact in which the content of aluminum oxide (Al₂O₃) accounts for 90 mass % or more in the total 100 mass % of the components constituting the dense ceramic body. The alumina sintered compact may contain at least one of silicon, magnesium, or calcium as an oxide, in addition to alumina. The cordierite sintered compact refers to a sintered compact in which the content of cordierite (2MgO.2Al₂O₃.5SiO₂) accounts for 90 mass % or more in the total 100 mass % of the components constituting the dense ceramic body. The cordierite sintered compact may contain alumina (2Al₂O₃), mullite and sapphirine ((Mg₄Al₄)(Al₄SiO₂)O₂₀), in addition to cordierite (2MgO.2Al₂O₃.5SiO₂).

The silicon carbide sintered compact refers to a sintered compact in which the content of silicon carbide (SiC) accounts for 90 mass % or more in the total 100 mass % of the components constituting the dense ceramic body. The silicon carbide sintered compact may contain boron, silicon, and carbon alone in addition to silicon carbide (SiC), and may be contained as silicide such as SiB₄ or SiB₆.

The aluminum nitride sintered compact refers to a sintered compact in which the content of aluminum nitride (AlN) accounts for 90 mass % or more in the total 100 mass % of the components constituting the dense ceramic body. The aluminum nitride sintered compact may contain at least one of silicon or iron as an oxide, in addition to silicon nitride (AlN).

The components constituting the alumina sintered compact, the silicon carbide sintered compact, and the aluminum nitride sintered compact may be identified by using an X-ray diffractometer (XRD) using CuKα beams, and then the content of the elements may be obtained by using a fluorescent X-ray analyzer (XRF) or an ICP emission spectrophotometer (ICP), and converted into the content of the identified components. The carbon contained alone in the silicon carbide sintered compact may be determined by using a carbon analyzer.

The components of the cordierite sintered compact may be identified by using the X-ray diffractometer (XRD) using CuKα beams, and then the content of each component may be determined by using a Rietveld method.

The body 4 of the present embodiment is circular in the plan view, and has a relatively large size with a thickness of 50 mm or more and a diameter of 350 mm or more. In the example illustrated in FIGS. 2 and 6, the diameter is D. The thickness of the body 4 may be 400 mm or less and the diameter may be 600 mm or less.

As illustrated in FIG. 2, the body 4 includes an upper surface 41 and a lower surface 42 parallel to each other, and a recess 3 is formed in the upper surface 41. The body 4 includes first channels 6 parallel to the upper surface 41 and the lower surface 42, and further includes second channels 7 between the first channels 6 and the upper surface 41. The thickness from the lower surface 42 to upper ends of the first channels 6 and the thickness from the upper ends of the first channels 6 from upper ends of the second channels 7 are preferably 20 mm or more and 50 mm or less, and more preferably 40 mm or less, respectively.

In the present embodiment, the first channel 6 serves as a suction path for vacuum-sucking the to-be-treated object 2. The first channels 6 are provided with, for example, concentrically, a plurality of suction holes 8 for connecting the first channels 6 and the recess 3 in the upper surface of the body 4. The suction hole 8 serves as a channel for suctioning air toward the lower surface 42 from the recess 3 by a suction device (not illustrated) such as a pump. The air sucked from the recess 3 is exhausted to the outside through the first channels 6, which are connected to the suction holes 8, via the suction holes 8.

On the other hand, the second channels 7 serve as channels through which a temperature control fluid flows, and is provided in a plural number, for example, concentrically. Temperature control fluids are categorized into two: for cooling and heating. For example, the temperature control fluid for cooling is cold water, air, helium gas, or the like, and the temperature control fluid for heating is hot water. Note that the second channel 7 is a channel independent of the first channel 6, and is not connected to the first channel 6.

The first channel 6 has a vertically long cross-sectional shape in which a depth d is greater than a width w. It is preferable that the depth d of the first channel should be at least twice the width w of the first channel 6. This makes it easy to degrease at the time of manufacturing of the body 4. In general, it may be difficult to degrease the inside of a relatively large dense ceramic body; however, although the channel member 1 of the present embodiment is a relatively large dense ceramic body, the inside of the body 4 can be quickly degreased. Particularly, the vertically long first channel 6 is easier to degrease than the horizontally long channel as disclosed in PTLs 1 and 2. That is, since the vertically long first channel 6 has a deep depth in the thickness direction, an organic binder volatilized from the inside of the body 4 is quickly discharged through the first channel 6, but in the case of the horizontally long channel, it takes time to discharge an organic binder volatilized at a deep portion (for example, a center portion) of the body 4. When the ratio of the volume (cross-sectional area) of the first channel 6 to the volume (cross-sectional area) of the body 4 is large, degreasing is easy, but the mechanical strength and rigidity of the body 4 are reduced. In a channel member having a relatively large thickness like the body 4 of the present embodiment, since the first channel 6 has a vertically long cross-sectional shape, the volume (cross-sectional area) of the first channel 6 can be made relatively large and the width of a partition wall between the channels can be made relatively large with respect to the channel width, which makes it possible to achieve both ease of degreasing and mechanical properties such as mechanical strength and rigidity. Particularly, when the channel member 1 is formed by bonding a plurality of ceramic substrates, the first channel 6 has a vertically long cross-sectional shape, so that the bonding area can be increased, resulting in an increase in the bonding strength. It is particularly preferable that the depth of the first channel 6 is at least half the thickness from the lower surface 42 of the body 4 to the upper end of the first channel 6.

The body 4, which is a dense ceramic body, may include a first ceramic substrate 43 including the first channels 6, a third ceramic substrate 45 located on the first ceramic substrate 43 and including the second channels 7 and lower portions of the suction holes 8, a second ceramic substrate 44 located on the third ceramic substrate 45 and including upper portions of the suction holes 8, a second ceramic bonding layer 17 between the first ceramic substrate 43 and the third ceramic substrate 45, and a third ceramic bonding layer 18 between the third ceramic substrate 45 and the second ceramic substrate 44.

Since the linear expansion coefficients of the first ceramic substrate 43, the second ceramic substrate 44, the third ceramic substrate 45, the second ceramic bonding layer 17, and the third ceramic bonding layer 18 can be substantially equivalent to one another, even when they are used in an environment where heating and cooling are repeated, they can be used for a long time.

The thickness of each of the second ceramic bonding layer 17 and the third ceramic bonding layer 18 is, for example, 40 μm or more and 60 μm or less.

The first channel 6 may include a first convex portion 20 connecting an inner peripheral surface (that is, a side surface) forming the first channel 6 and a lower surface (that is, an upper surface of the first channel 6) of the third ceramic substrate 45. That is, the first convex portion 20 connecting the upper surface and the side surface of the first channel 6 may be provided.

The first convex portion 20 improves the bonding strength between the inner peripheral surface forming the first channel 6 and the lower surface of the third ceramic substrate 45 and can secure the airtightness in the second channel 6, resulting in further improvement in resistance to mechanical disturbance such as vibration. The first convex portion 20 has, for example, an annular shape extending along the first channel 6 having an annular shape.

The second channel 7 may include a second convex portion 21 connecting an inner peripheral surface forming the second channel 7 and a lower surface of the second ceramic substrate 44. That is, the second convex portion 21 connecting an upper surface and a side surface of the second channel 7 may be provided.

The second convex portion 21 improves the bonding strength between the inner peripheral surface forming the second channel 7 and the lower surface of the second ceramic substrate 44, resulting in the improvement in resistance to mechanical disturbance such as vibration.

At least one of the first convex portion 20 or the second convex portion 21 is annular. As used herein, the term “annular” encompasses an intermittent annular shape.

At least one of the first convex portion 20 or the second convex portion 21 includes a dense ceramic body having a plurality of closed pores, and an average value of aspect ratios of the closed pores may be 2 or less.

The aspect ratio of the closed pores is a value indicating a maximum length of the closed pores with respect to a minimum width of the closed pores as a ratio, and the closer this value is to 1, the closer it is to a perfect circle.

The plurality of closed pores relieve stress, and when the average value of the aspect ratios of the closed pores is 2 or less, the number of closed pores close to a true sphere increases, so that stress generated around the closed pores is reduced and cracks originating from the periphery are less likely to occur.

The aspect ratio of the closed pores included in each of the first convex portion 20 and the second convex portion 21 may be measured, for example, by observing a cross-section by using a scanning electron microscope. A sample including a part of the first convex portion 20 and the second convex portion 21 to be measured is cut and embedded in a polyester-based resin to prepare a columnar sample. The cross-section of the sample may be mirror-finished by using diamond abrasive grains. The magnification may be set to, for example, 500 times. As an observation range in which the cross-section of the sample is observed, for example, a horizontal length may be set to 256 μm and a vertical length may be set to 192 μm.

Each observation range is targeted for analysis, and the minimum width and the maximum length of each closed pore may be calculated by applying a technique called particle analysis of image analysis software “Azo-kun (ver2.52)” (trade name, manufactured by Asahi Kasei Engineering Corporation), and the aspect ratio may be calculated.

In the analysis, conditions for the particle analysis are set as follows: the brightness of particles is set to dark, the binarization method is set to manual, the threshold value is set to 70 to 100, the small figure removal area is set to 0.3 μm², and the noise removal filter is set to presence.

In the measurement described above, the threshold value is set to 70 to 100; however, the threshold value may be adjusted according to the brightness of an image in the observation range, the brightness of particles may be set to dark, the binarization method may be set to manual, the small figure removal area may be set to 0.3 μm², and the noise removal filter may be set to presence, and then the threshold value may be adjusted so that a marker appearing in the image matches the shape of the closed pores.

Similarly to the first channel 6, it is preferable that the second channel 7 should have a vertically long shape in which a depth is greater than a width and it is particularly preferable that the depth of the second channel 7 should be at least twice the width of the second channel 7. With this, similarly to the first channel 6, the body 4 is easy to degrease at the time of manufacturing and strong in mechanical properties such as mechanical strength and rigidity, and when a temperature control fluid is flowed into the second channel 7, the volume (cross-sectional area) of the second channel 7 can be made greater than that of the horizontally long channel, so that the uniformity of temperature distribution and the response of temperature control are improved. It is particularly preferable that the depth of the second channel 7 is at least half the thickness from the upper end of the first channel 6 to the upper end of the second channel.

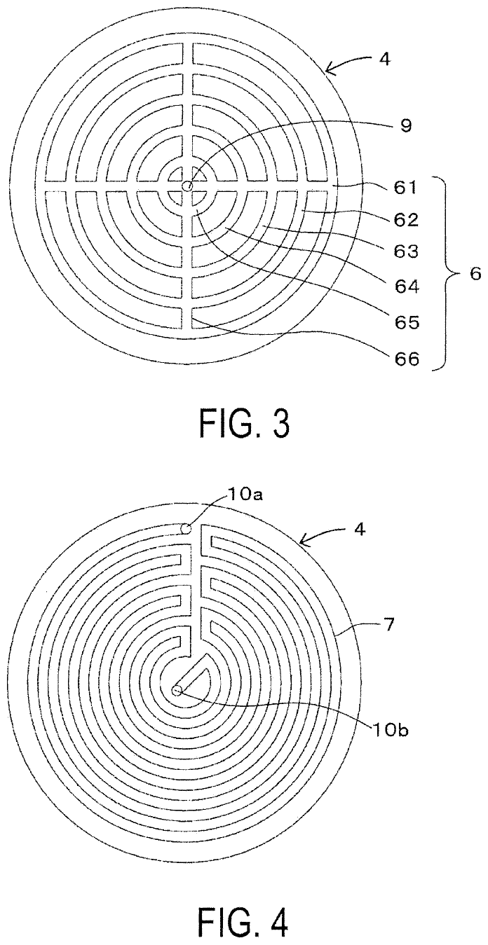

FIG. 3 is a plan view illustrating the first channel 6 used as a suction path for vacuum suction. As illustrated in the FIG. 3, the first channel 6 includes a plurality of annular channels 61 to 65 concentrically disposed from the center to the peripheral edge of the body 4, and a plurality of connection channels 66 extending in the radial direction from the center of the body 4, and the plurality of channels 61 to 65 communicate with each other by the plurality of connection channels 66. An exhaust hole 9 is provided in the center of the body 4, and air in the annular channels 61 to 65 and the connection channels 66 is exhausted from the lower surface 42 of the body 4 through the exhaust hole 9.

FIG. 4 is a plan view illustrating the second channel 7 through which the temperature control fluid flows. As illustrated in the FIG. 4, the second channel 7 is provided at one end thereof with a fluid inflow hole 10a and at the other end thereof with a fluid outflow hole 10b, and is disposed between the fluid inflow hole 10a and the fluid outflow hole 10b so as to connect the fluid inflow hole 10a and the fluid outflow hole 10b. In order to increase the efficiency of the temperature control function, it is preferable that the second channel 7 should be disposed as densely as possible in a plane parallel to the upper surface 41 and the lower surface 42 of the body 4. The fluid inflow hole 10a is connected to a connection hole (not illustrated) provided in a side wall, and causes a fluid to flow in from the outside. The fluid outflow hole 10b extends to the lower surface 42 of the body 4 and discharges the fluid from the lower surface 42. It is preferable that the fluid should circulate to and from a heat exchanger (not illustrated).

In contrast to the above, the fluid inflow hole 10a may be used as a fluid outflow hole flow, and the fluid outflow hole 10b may be used as a fluid inflow hole. Both the fluid inflow hole 10a and the fluid outflow hole 10b may be connected to the lower surface 42 to supply a fluid, and may be connected to the side surface to supply a fluid.

The porous body 5 supports the to-be-treated object 2, and air in the recess 3 is exhausted to the outside by the first channel 6, thereby sucking the to-be-treated object 2. The porous body 5 is made of, for example, breathable porous ceramics. Examples of the available porous ceramics include those made of a plurality of ceramic particles and glass for bonding the ceramic particles to each other and in which gaps of open pores are formed between the ceramic particles, the plurality of ceramic particles being made of ceramics that are the same material as the ceramic sintered compact of the main body 4. The porosity of the porous body 5 is preferably in the range from 25 to 50%. The porosity of the porous body 4 may be determined in accordance with JIS R 1634:1998. The channel member 1 may not include the porous body 5, but may have holes (and grooves) for suction on the upper surface of the body 4 consisting essentially of the dense body to suck and support the to-be-treated object 2.

When the first channel 6 and the second channel 7 have a large cross-sectional area or a narrow pitch from a central region to an outer peripheral region in the plan view, it is easy to degrease the outer peripheral region having a large area (volume). When a communication hole with the outside which becomes a degreasing hole is formed not only on a side surface but also on the upper surface 41 and the lower surface 42, it is easy to degrease the central region far from the side surface.

The channel member 1 described above can suck the to-be-treated object 2 as follows. First, the to-be-treated object 2 is placed on the upper surface of the channel member 1. At this time, as illustrated in FIG. 2, the inner region of the to-be-treated object 2 is placed on the upper surface of the porous body 5 so as to cover the entire porous body 5, and the region of an outer edge of the to-be-treated object 2 is placed on the upper surface 41 of the body 4. Next, air is sucked into the first channel 6 from the recess 3 via the suction holes 8 of the body 4, and is discharged to the outside from the first channel 6. As a consequence, the to-be-treated object 2 is sucked through the gap of the porous body 5 due to a decrease in the air pressure in the recess 3, so that the to-be-treated object 2 is sucked on the upper surface 41 of the channel member 1.

The channel member 1 can cool or heat the sucked to-be-treated object 2 by flowing a cooling or heating fluid through the second channel 7. As a consequence, when the to-be-treated object 2 is machined, the temperature of the to-be-treated object 2 can be kept uniform, and the machining accuracy of the to-be-treated object 2 can be increased.

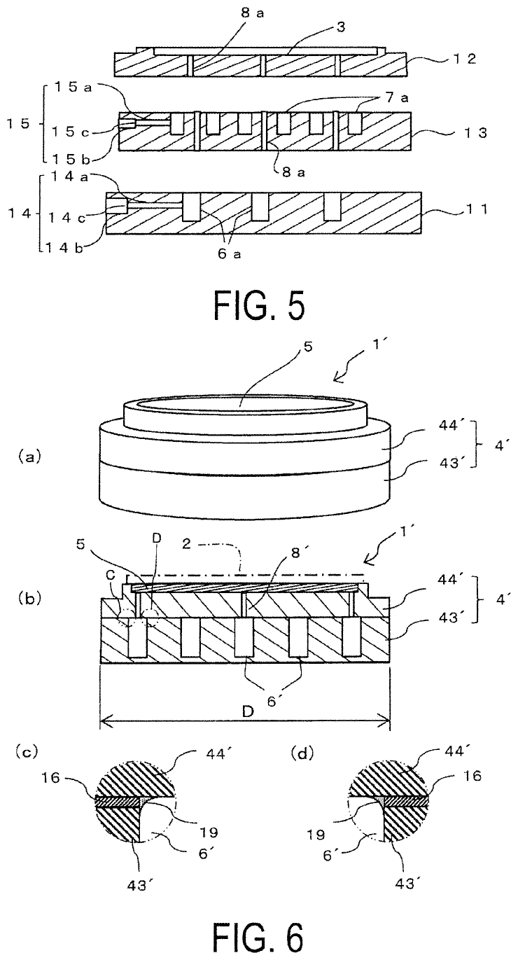

A method for manufacturing the channel member 1 described above will be described with reference to FIG. 5.

First, when a dense ceramic body is an alumina sintered compact, a mixed powder is prepared by weighing to contain 0.3 to 0.42 mass % of magnesium hydroxide as expressed in terms of oxide (MgO), 0.03 to 0.05 mass % of silicon oxide, 0.01 to 0.02 mass % of calcium carbonate as expressed in terms of oxide (CaO), and an aluminum oxide as the remainder. The mixed powder is fed together with a solvent, such as water, into a tumbling mill and is crushed by using ceramic balls made of an aluminum oxide with a purity of 99.5 mass % or more and 99.99 mass % or less so as to have a predetermined particle size.

Next, an organic binder such as polyvinyl alcohol, polyethylene glycol, or acrylic resin is added and then mixed to produce a slurry. The amount of the organic binder added is 2 parts by mass or more and 10 parts by mass or less in total relative to 100 parts by mass of the mixed powder.

Next, the slurry is granulated by spray drying. A powder compact is produced from the granulated ceramic powder by using various forming methods, for example, a cold isostatic pressing (CIP) method and setting the forming pressure to, for example, 80 MPa or more and 150 MPa or less. In this case, it is preferable that a first powder compact 11, a second powder compact 12, and a third powder compact 13 to be described below should be produced so that main components in the dense ceramic body have the same composition.

Next, the second powder compact 12 is made by cutting so that the recess 3 is formed on an upper surface and a lower surface becomes a flat surface. The first powder compact 11 is made so that the vertically long first grooves 6a are formed on an upper surface and a lower surface becomes a flat surface. The third powder compact 13 is made so that the vertically long second grooves 7a are formed on an upper surface and a lower surface becomes a flat surface. The first grooves 6a and the second grooves 7a each have a vertically long cross-sectional shape. When the depth of the first grooves 6a is at least half the thicknesses of the first powder compact 11 and the depth of the second grooves 7a is at least half the thicknesses of the third powder compact 13, degreasing is easy.

It is preferable that through holes 8a to be the suction holes 8 should be formed in the second powder compact 12 and the third powder compact 13.

Next, a bonding paste containing ceramic powder is applied to at least one of the upper surface of the first powder compact 11, which is formed with the first grooves 6a, or the lower surface of the third powder compact 13. A bonding paste containing ceramic powder is applied to at least one of the upper surface of the third powder compact 13, which is formed with the second grooves 7a, or the lower surface of the second powder compact 12.

Next, the upper surface of the first powder compact 11 and the lower surface of the third powder compact 13 are superimposed via the bonding paste, and the upper surface of the third powder compact 13 and the lower surface of the second powder compact 12 are superimposed via the bonding paste, thereby a laminated body is formed in which the first powder compact 11, the third powder compact 13, and the second powder compact 12 are laminated in this order from below.

The laminated body is heated at a temperature lower than a firing temperature to degrease, and is fired to produce the body 4. That is, the body 4 consisting essentially of one dense ceramic body is manufactured by simultaneously firing the first powder compact 11, the third powder compact 13, the second powder compact 12, and the bonding paste. It is preferable that the firing atmosphere should be an atmospheric atmosphere, and the firing temperature should be, for example, 1,400° C. or more and 1,800° C. or less.

By so doing, it is possible to produce a channel member consisting essentially of a circular dense ceramic body having a thickness of 50 mm or more and a diameter of 350 mm or more.

As the aforementioned bonding paste, a mixture of the above mixed powder, solvent, and cellulosic polysaccharide is used. Specifically, solvent such as pure water or ethanol is added to the mixed powder so that a volume ratio of the mixed powder to the solvent is 55/45 to 60/40, and the total of the solvent and the mixed powder is 100 parts by mass. 8 to 20 parts by mass or less of the cellulosic polysaccharide is added to 100 parts by mass of the total of the solvent and the mixed powder, and these are placed into a storage container in a stirring apparatus, mixed and stirred to produce a bonding paste.

Here, the cellulose-based polysaccharide is, for example, at least one of methyl cellulose, ethyl cellulose, ethyl methyl cellulose, hydroxymethyl cellulose, hydroxypropyl methyl cellulose, hydroxyethyl methyl cellulose, carboxymethyl cellulose, carboxymethyl ethyl cellulose, or carboxyethyl cellulose.

As the above mixed powder, a mixed powder having the same main component as the mixed powder used for the powder compact of the body 4 is used. As a consequence, it is possible to produce the body 4 consisting essentially of one ceramic sintered compact having the same composition as the main component by simultaneously firing the bonding paste with the second powder compact 12, the third powder compact 13, and the first powder compact 11.

As long as the second powder compact 12, the third powder compact 13, and the first powder compact 11 can be integrated, a bonding paste having another composition may be used. The first convex portion 20 and the second convex portion 21 can be formed by applying a bonding paste between the first powder compact 11 and the third powder compact 13 so as to protrude into the first channel 6, for example, when the first powder compact 11, the second powder compact 12, and the third powder compact 13 illustrated in FIG. 5 are laminated via the bonding paste.

When the dense ceramic body is a silicon carbide sintered compact, a mixed powder, which is prepared by weighing a powder that is a sintering aid such as boron carbide, phenol, rare earth oxide, and aluminum oxide, and a powder consisting essentially of silicon carbide as a main component, is fed together with a solvent, such as water, into a tumbling mill and is crushed by using ceramic balls so as to have a predetermined particle size.

Next, after adding an organic binder, a slurry is produced. The organic binder is only required to be a synthetic resin: rosin ester, ethyl cellulose, ethyl hydroxyethyl cellulose, butyral resin, phenol resin, polyethylene oxide resin, poly (2-ethyloxazoline) resin, polyvinylpyrrolidone resin, polyacrylic acid resin, polymethacrylic acid resin, polyvinyl alcohol resin, acrylic resin, polyvinyl butyral resin, alkyd resin, polybenzyl, poly m-divinylbenzene, polystyrene, and the like can be used.

Next, the slurry is sequentially granulated, formed, and cut by the method described above to produce the first powder compact 11, the second powder compact 12, and the third powder compact 13, and then a bonding paste is applied to the surface of each of the powder compacts to be bonded.

Here, as the bonding paste used, a mixture of the above mixed powder, solvent, and organic binder is used.

The organic binder is one or more of aromatic resins such as a phenol resin, polybenzyl, poly m-divinylbenzene, a polyvinylpyrrolidone resin, and polystyrene, and is added in a larger amount than the amount of the organic binder added to the slurry.

Then, a bonding paste is applied to the surface of each of the powder compacts to be bonded, and the powder compacts are laminated together, dried, and then held in nitrogen gas at a predetermined temperature to produce a degreased body. The channel member can be produced by holding the degreased body for 3 hours to 10 hours with the firing atmosphere set to an argon gas atmosphere and the firing temperature set to 1,900° C. or higher and 2,050° C. or lower.

The degreasing described above may be performed at a temperature lower than the firing temperature, preferably and usually 400 to 800° C. At this time, the organic binder contained in each of the powder compacts is volatilized and discharged from holes that become the exhaust hole 9, the fluid inflow hole 10a, and the fluid outflow hole 10b of the channel member 1; however, as illustrated in FIG. 5, in order to efficiently discharge the organic binder in a short time, a hole having one end connected to the groove 6a of the first powder compact 11 and the other end communicating from the side surface of the first powder compact 11 to the outside, that is, a degreasing passage 14 may be provided. The degreasing passage 14 is closed by inserting a dense ceramic body, a closing plug (not illustrated) made of metal such as stainless steel, or the like after firing, and bonding the closing plug with molten glass.

A degreasing passage 15 may also be provided in the third powder compact 13.

The degreasing passage 15 is also closed by bonding the above closing plug with molten glass after firing.

It is preferable that at least one of the degreasing passage 14 or the degreasing passage 15 should have the surface of the glass used for bonding being flush with the outer peripheral surface of the body 4 in order to prevent the closing plug from being exposed to the outside. This improves the commercial value and enables the airtightness to be maintained. Particularly when the degreasing passage is closed by the closing plug made of metal, it is possible to suppress the desorption of metal particles, which is likely to occur from the closing plug, contamination due to floating of the particles can be prevented. In order to make the surface of the glass flush with the outer peripheral surface of the body 4, after the closing plug or the like is inserted, glass may be filled from the outside, melted, and cooled, and then a part of the glass exposed to the outside may be grounded or polished.

At least one of the degreasing passage 14 or the degreasing passage 15 may be provided in a plural number, for example, 4 or more and 8 or less along the radial direction. With such a configuration, the organic binder can be more efficiently volatilized and discharged.

In this case, the degreasing passage 14 (15) may be disposed at equal intervals along the circumferential direction. With such a configuration, the organic binder can be volatilized and discharged without bias.

The degreasing passage 14 may have, for example, a circular cross-section, and the diameter of an inner peripheral surface 14b on the outer side of the first powder compact 11 forming the laminated body may be greater than that of an inner peripheral surface 14a on the groove 6a side. Such a configuration reduces the possibility that the organic binder stays in the vicinity of an opening through which the degreasing passage 14 opens to the outside, and thus the organic binder can be efficiently discharged. The cross-section of the degreasing passage 14 is a cross-section perpendicular to the axial direction of the degreasing passage 14.

The inner peripheral surface of the degreasing passage 14 may be expanded so as to incline from the groove 6a side toward the outer side of the first powder compact 11, and as illustrated in FIG. 5, the inner peripheral surface 14a and the inner peripheral surface 14b may be connected by an annular stepped surface 14c.

The degreasing passage 15 may have, for example, a circular cross-section, and a diameter 15b on the outer side of the third powder compact 13 forming the laminated body may be greater than a diameter 15a on the groove 7a side. Such a configuration reduces the possibility that the organic binder stays in the vicinity of an opening through which the degreasing passage 15 opens to the outside, and thus the organic binder can be efficiently discharged. The cross-section of the degreasing passage 15 is a cross-section perpendicular to the axial direction of the degreasing passage 15.

The inner peripheral surface of the degreasing passage 15 may be expanded so as to incline from the groove 7a side toward the outer side of the third powder compact 13, and as illustrated in FIG. 5, the inner peripheral surface 15a and the inner peripheral surface 155b may be connected by an annular stepped surface 15c.

Another embodiment of the present disclosure will be described with reference to FIGS. 6(a) and 6(b). The same constituent members as those in the aforementioned embodiment are denoted by the same reference numerals, and descriptions thereof will be omitted.

As illustrated in FIGS. 6(a) and 6(b), a channel member 1′ of the present embodiment includes a first channel 6′ parallel to an upper surface and a lower surface parallel to each other of a body 4′. The first channel 6′ is a suction path for suction for vacuum-sucking a to-be-treated object, and includes suction holes 8′ opened to the upper face of the body 4′.

The first channel 6′ is not limited to the suction path for suction, and may be a channel through which a temperature control fluid flows. In this case, the above suction holes 8′ are not required.

In the configurations of FIGS. 2 and 6, the depths of the first channels 6 and 6′ or the depth of the second channels 7 may be increased inside the channel member 1 or 1′ (inner region including the center in the plan view of the channel member 1), and may be decreased outside (region located on the outside and including an outer peripheral surface in the plan view of the channel member 1). Such a configuration can promote degreasing in the inner region where a distance from the outer peripheral surface is long and degreasing is difficult. When the effect of the present disclosure is exhibited by adjusting the depths of the plurality of first channels 6 and 6′ or the depth of the second channels 7 in this manner, there may be a channel having a depth less than twice a width in a part (for example, a part of the outer region).

The body 4′, which is a dense ceramic body, may include a first ceramic substrate 43′, a second ceramic substrate 44′ located on the first ceramic substrate 43′, and a first ceramic bonding layer 16 between the first ceramic substrate 43′ and the second ceramic substrate 44′.

The linear expansion coefficients of the first ceramic substrate 43′, the second ceramic substrate 44′, and the first ceramic bonding layer 16 can be substantially equivalent to one another, and in this case, even when they are used in an environment where heating and cooling are repeated, the strain accumulated in each of the members is reduced, so that they can be used for a long time.

The thickness of the first ceramic bonding layer 16 is, for example, 40 μm or more to 60 μm or less.

The first channel 6′ may include a first convex portion 19 connecting an inner peripheral surface forming the first channel 6′ and a lower surface of the second ceramic substrate 44′. That is, the first convex portion 19 connecting the upper surface and the side surface of the first channel 6′ may be provided. The first convex portion 19 can be formed in the same manner as the first convex portion 20 described above.

The first protruding portion 19 improves the bonding strength between the inner peripheral surface forming the first channel 6′ and the lower surface of the second ceramic substrate 44′, resulting in the improvement in resistance to mechanical disturbance such as vibration. The first convex portion 19 has, for example, an annular shape extending along the first channel 6′ having an annular shape. The first convex portion 19 may connect the lower surface and the side surface of the first channel 6′. Even in this case, the resistance to mechanical disturbance such as vibration is improved.

The first convex portion 19 includes a dense ceramic body having a plurality of closed pores, and an average value of aspect ratios of the closed pores may be 2 or less.

The plurality of closed pores relieve stress, and when the average value of the aspect ratios of the closed pores is 2 or less, the number of closed pores close to a true sphere increases, so that stress generated around the closed pores is reduced and cracks originating from the periphery are less likely to occur. The aspect ratio of the closed pores included in the first convex portion 19 may be measured by the same method as described above.

Similarly to laminating the first powder compact 11, the second powder compact 12, and the third powder compact 13 illustrated in FIG. 5 via a bonding paste, such a first protruding portion 19 can be formed, for example, by applying a bonding paste between a powder compact forming the first ceramic substrate 43′ and a powder compact forming the second ceramic substrate 44′ so as to protrude into the first channel 6′.

The manufacturing method of the channel member 1′ of the present embodiment may be basically the same as that of the channel member of the embodiment described above except that two powder compacts are laminated instead of three powder compacts. That is, a channel member consisting essentially of a dense ceramic body can be manufactured by preparing a first powder compact and a second powder compact made by forming a ceramic powder, forming a groove on the upper surface of the first powder compact so that the groove is configured to be a first channel having a depth greater than a width, forming a laminated body in which the first powder compact and the second powder compact are laminated via a bonding paste including the above ceramic powder, and degreasing and firing the laminated body.

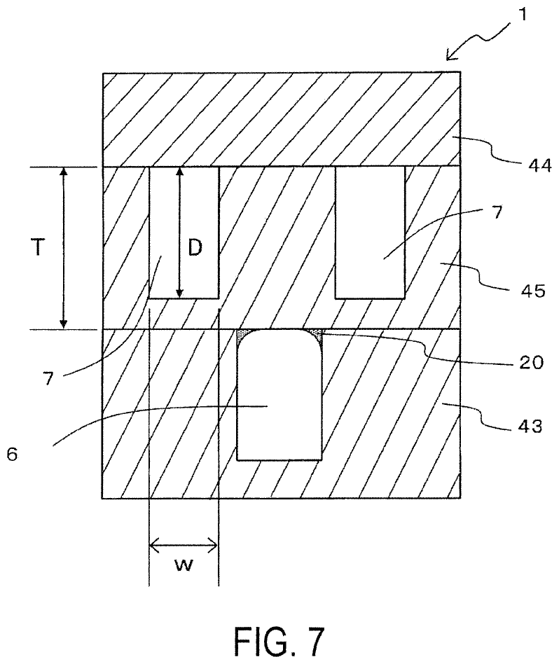

A channel member according to further another embodiment of the present disclosure will be described with reference to FIG. 7. The same members as those in FIGS. 1 to 5 are denoted by the same reference numerals, and descriptions thereof will be omitted.

As illustrated in FIG. 7, a channel member 1 of the present embodiment includes a dense ceramic body consisting essentially of a plurality of laminated stages (three layers in FIG. 7) of ceramic substrates. Specifically, in the present embodiment, the dense ceramic body consists of a first ceramic substrate 43, a second ceramic substrate 44, and a third ceramic substrate 45. These ceramic substrates 43, 44, and 45 can be formed, for example, from the first powder compact 11, the second powder compact 12, and third powder compact 13 described above.

Except for the second ceramic substrate 44 on the uppermost layer, the ceramic substrates (the first ceramic substrate 43 and the third ceramic substrate 45) include a first channel 6 and a second channel 7, respectively. A depth D of the second channel 7 of the upper third ceramic substrate 45 laminated on the first ceramic substrate 43 located below is greater than a width w of the second channel 7, and is greater than half of a thickness T of the third ceramic substrate 45.

This reduces a distance between the upper and lower channels 6 and 7. Therefore, at the time of manufacturing, degreasing can be efficiently performed from a horizontal direction and a vertical direction in the upper and lower channels 6 and 7.

The first channel 6 of the first ceramic substrate 43 may also have a depth greater than half of the thickness of the first ceramic substrate 43. Even when the channel member 1 consists of four or more layers of ceramic substrate, a ceramic substrate vertically interposed between other ceramic substrates may have a channel having a depth greater than half of the thickness of the ceramic substrate.

As illustrated in FIG. 7, a first convex portion 20 may be provided on an inner upper portion of the first channel 6. With this, the strength can be reinforced by the first convex portion 20 even though the distance between the channels 6 and 7 is reduced.

Although the embodiments of the present disclosure have been described above, the present disclosure is not limited to the above embodiments and various changes and improvements can be made. For example, in the embodiments described above, the channel member has a circular planar shape; however, the planar shape may be a polygon such as a quadrangle. At this time, it is preferable that the channel member should have a thickness of 50 mm or more and an area in the plan view equal to or greater than that of a circle with a diameter of 350 mm.

### REFERENCE SIGNS LIST

1, 1′, 15 Channel member
2 To-be-treated Object
3 Recess
4, 4′ Body
41 Upper surface
42 Lower surface
43, 43′ First ceramic substrate
44, 44′ Second ceramic substrate
45 Third ceramic substrate
5 Porous body
6 First channel
7 Second channel
8 Suction hole
9 Exhaust hole
10a Fluid inflow hole
10b Fluid outflow hole
11 First powder compact
12 Second powder compact
13 Third powder compact
14 Degreasing passage
14a, 15a Inner peripheral surface
14b, 15b Inner peripheral surface
14c, 15c Stepped surface
16 First ceramic bonding layer
17 Second ceramic bonding layer
18 Third ceramic bonding layer
19, 20 First convex portion
21 Second convex portion

1. A channel member comprising:
a dense ceramic body including an upper surface and a lower surface with a thickness of 50 mm or more between the upper surface and the lower surface and having an area in a plan view equal to or greater than an area of a circle with a diameter of 350 mm, wherein
the dense ceramic body comprises a first channel inside, wherein
a depth of the first channel is greater than a width of the first channel.

2. The channel member according to claim 1, wherein the depth of the first channel is at least twice the width of the first channel.

3. The channel member according to claim 1, wherein the depth of the first channel located inside the channel member is greater than the depth of the first channel located outside the channel member.

4. The channel member according to claim 1, wherein the upper surface and the lower surface are parallel to each other, and the first channel is parallel to the upper surface and the lower surface.

5. The flow member according to claim 1, wherein the first channel includes a first convex portion connecting an upper surface and a side surface of the first channel.

6. The channel member according to claim 5, wherein the first convex portion comprises a dense ceramic body having a plurality of closed pores, and an average value of aspect ratios of the closed pores is 2 or less.

7. The channel member according to claim 1, further comprising a second channel between the first channel and the upper surface,
wherein
a depth of the second channel along a direction of the thickness is greater than a width of the second channel.

8. The channel member according to claim 7, wherein the depth of the second channel is at least twice the width of the second channel.

9. The channel member according to claim 7, wherein the depth of the second channel located inside the channel member is greater than the depth of the second channel located outside the channel member.

10. The channel member according to claim 7, wherein the dense ceramic body includes a plurality of suction holes for connecting the first channel and the upper surface to suck a to-be-treated object, and the second channel is a channel through which a temperature control fluid flows.

11. The flow member according to claim 7, wherein the second channel includes a second convex portion connecting an upper surface and a side surface of the second channel.

12. The channel member according to claim 11, wherein the second convex portion comprises a dense ceramic body having a plurality of closed pores, and an average value of aspect ratios of the closed pores is 2 or less.

13. A channel member comprising:
a dense ceramic body including an upper surface and a lower surface with a thickness of 50 mm or more between the upper surface and the lower surface and having an area in a plan view equal to or greater than an area of a circle with a diameter of 350 mm, wherein
the dense ceramic body comprises three or more laminated layers of ceramic substrates,
except for a ceramic substrate on the uppermost layer, each of the ceramic substrates include a channel,
and for the ceramic substrates including a channel, a ceramic substrate located above is laminated on the ceramic substrate located below, and
a depth of the channel of the ceramic substrate located above is greater than a width of the channel of the ceramic substrate located above, and is greater than half of a thickness of the ceramic substrate located above.

14. A method for manufacturing a channel member, the method comprising:
preparing a first powder compact and a second powder compact made by forming a ceramic powder;
forming a groove on an upper surface of the first powder compact, the groove being configured to be a first channel having a depth greater than a width; applying a bonding paste containing the ceramic powder to at least one of the upper surface of the first powder compact, which is formed with the groove, or a lower surface of the second powder compact;
forming a laminated body in which the first powder compact and the second powder compact are laminated via the bonding paste;
heating the laminated body at a temperature lower than a firing temperature to degrease the laminated body; and
producing a channel member by firing the laminated body, the channel member consisting essentially of a dense ceramic body having a thickness of 50 mm or more and an area in a plan view equal to or greater than an area of a circle with a diameter of 350 mm.

15. The method according to claim 14, wherein the groove includes a hole communicating with an outside of the laminated body in a state in which the first powder compact and the second powder compact are laminated.

16. The method according to claim 15, wherein the hole has a circular cross-section, and a diameter on an outer side of the laminated body is greater than a diameter on a side of the groove.

17. The method according to claim 14, wherein the first powder compact, the second powder compact, and the bonding paste are produced by using a ceramic powder having the same main component.

18. A method for manufacturing a channel member, the method comprising:
preparing a first powder compact, a second powder compact, and a third powder compact made by forming a ceramic powder;
forming a first groove on an upper surface of the first powder compact, the first groove being configured to be a first channel having a depth greater than a width, and forming a second groove on an upper surface of the third powder compact, the second groove being configured to be a second channel having a depth greater than a width;
applying a bonding paste containing the ceramic powder to at least one of the upper surface of the first powder compact, which is formed with the first groove, or a lower surface of the third powder compact;
applying a bonding paste containing the ceramic powder to at least one of the upper surface of the third powder compact, which is formed with the second groove, or a lower surface of the second powder compact;
superimposing the upper surface of the first powder compact and the lower surface of the third powder compact via the bonding paste, and superimposing the upper surface of the third powder compact and the lower surface of the second powder compact via the bonding paste, thereby forming a laminated body in which the first powder compact, the third powder compact, and the second powder compact are laminated in this order;
heating the laminated body at a temperature lower than a firing temperature to degrease the laminated body; and
producing a channel member by firing the laminated body, the channel member consisting essentially of a dense ceramic body having a thickness of 50 mm or more and an area in a plan view equal to or greater than an area of a circle with a diameter of 350 mm.

19. The method according to claim 18, wherein each of the first groove and the second groove includes a hole communicating with an outside of the laminated body in a state in which the first powder compact, the third powder compact, and the second powder compact are laminated in this order.
